(19) United States
(12) Patent Application Publication
(10) Pub. No.: US 2024/0312818 A1
(43) Pub. Date: Sep. 19, 2024

(54) APPARATUS FOR TRANSPORTING SEMICONDUCTOR WAFER

(71) Applicant: UK ROBOTICS. CO., LTD., Ulsan (KR)

(72) Inventor: Woo Jong YOO, Ulsan (KR)

(73) Assignee: UK ROBOTICS. CO., LTD., Ulsan (KR)

(21) Appl. No.: 18/574,728

(22) PCT Filed: Dec. 1, 2021
(86) PCT No.: PCT/KR2021/018017

§ 371 Date: Dec. 27, 2023

(30) Foreign Application Priority Data
Nov. 4, 2021 (KR) 10-2021-0150718

(51) Int. Cl. H01L 21/677; H01L 21/687

(52) U.S. Cl. CPC H01L 21/67742; H01L 21/67754; H01L 21/68707

(57) ABSTRACT

A semiconductor wafer transporting apparatus includes a fixed hand and a plurality of movable hands which support semiconductor wafers, a fixed frame of which one end is coupled to the fixed hand to support the fixed hand, a plurality of movable frames of which one ends are coupled to the movable hands to vertically move the movable hands, a pair of first sliders which are coupled to the other ends of a pair of movable frames among the movable frames and vertically move the pair of movable frames according to rotation of a first ball screw, and a pair of second sliders which are coupled to the other ends of another pair of movable frames among the movable frames and vertically move the another pair of movable frames according to rotation of a second ball screw.

### TECHNICAL FIELD

The present invention relates to a semiconductor wafer transporting apparatus, and more specifically, to a semiconductor wafer transporting apparatus that allows a distance between hands, which accommodate and support a wafer, to be easily adjusted.

### BACKGROUND ART

Multiple layers with circuit patterns are formed on a semiconductor wafer through diffusion, etching, chemical vapor deposition, cutting, metal deposition processes to manufacture semiconductor elements, and the semiconductor wafer is necessarily moved to devices or chambers.

Generally, in order to perform a unit process, the semiconductor wafer transporting apparatus transports the semiconductor wafers from a cassette, which is a storage device, to the chamber or from the chamber to the cassette.

The semiconductor transporting apparatus generally transports the semiconductor wafers in units of one or five wafers while hands accommodate and support the semiconductor wafers. In this case, a structure capable of fixing the semiconductor wafers to prevent the semiconductor wafers from shaking on or escaping from the hands and components for adjusting positions of the semiconductor wafers are required.

In addition, In the case of the conventional semiconductor wafer transporting apparatus, distances/heights of the hands should be manually adjusted according to set distances between the semiconductor wafers in the cassette in order to unload the semiconductor wafers from the cassette or store the semiconductor wafers in the cassette. As described above, when the distances/heights of the hands are adjusted manually, a process may be delayed, and it is difficult to secure accuracy of the adjustment of the distances/heights.

### Technical Problem

The present invention is directed to providing a semiconductor wafer transporting apparatus that allows a position of a semiconductor wafer and distances/heights of hands to be adjusted.

Technical objectives of the present invention are not limited to the above-described technical objectives, and other technical objectives that are not described may be clearly understood to those skilled in the art from the following descriptions.

### Technical Solution

One aspect of the present invention provides a semiconductor wafer transporting apparatus including a fixed hand and a plurality of movable hands which support semiconductor wafers, a fixed frame of which one end is coupled to the fixed hand to support the fixed hand, a plurality of movable frames of which one ends are coupled to the movable hands to vertically move the movable hands, a pair of first sliders which are coupled to the other ends of a pair of movable frames among the movable frames and vertically move the pair of movable frames according to rotation of a first ball screw, and a pair of second sliders which are coupled to the other ends of another pair of movable frames among the movable frames and vertically move the another pair of movable frames according to rotation of a second ball screw.

The fixed hand may be positioned at a middle of the movable hands, and the fixed frame may be positioned at a middle of the movable frames.

Rotational speeds of the first ball screw and the second ball screw may be different, and movement speeds of the first sliders and the second sliders may be different. The first sliders may move in opposite directions according to the rotation of the first ball screw, and the second sliders may move in opposite directions according to the rotation of the second ball screw.

The semiconductor wafer transporting apparatus may further include a fixed cylinder which provides power to a stopper positioned at one side of the fixed hand to adjust a position of the semiconductor wafer on the fixed hand, a plurality of movable cylinders which provide power to stoppers positioned at one sides of the movable hands to adjust positions of the semiconductor wafers on the movable hands, and a guide block which provides vertical movement passages of the movable cylinders.

The movable cylinders may vertically move according to the movement of the movable frames.

The guide block may include a sidewall coupled to the fixed cylinder, a first guide rail vertically formed and coupled to some movable cylinders among the movable cylinders, and a second guide rail vertically formed and coupled to the remaining movable cylinders among the movable cylinders.

The fixed frame and the movable frames may have hollows to accommodate the guide block therein.

The semiconductor wafer transporting apparatus may further include a plurality of connectors connected between the fixed cylinder and the stopper and connected between the movable cylinders and the stoppers. The connectors may move through openings formed at one ends of the fixed frame and the movable frames, and each of the connectors may include a pair of latching hooks formed on one surface thereof to limit a movement range of the stopper.

The semiconductor wafer transporting apparatus may further include a first pully coupled to the first ball screw, a second pully coupled to the second ball screw, and a driving part which drives the first pully and the second pully, wherein rotational ratios of the first pully and the second pully may be differently set in consideration of movement speeds and movement distances of the movable frames.

One aspect of the present invention provides a semiconductor wafer transporting apparatus including a plurality of movable hands which support semiconductor wafers, a plurality of stoppers positioned at one sides of the movable hands to adjust positions of the semiconductor wafers on the movable hands, a plurality of movable frames of which one ends are coupled to the movable hands to vertically move the movable hands, a pair of first sliders which are coupled to the other ends of a pair of movable frames among the movable frames and vertically move the pair of movable frames according to rotation of a first ball screw, a pair of second sliders which are coupled to the other ends of another pair of movable frames among the movable frames and vertically move the another pair of movable frames according to rotation of a second ball screw, and a plurality of movable cylinders which vertically move according to the movement of the movable frames and provide power to the stoppers.

### Advantageous Effects

A semiconductor wafer transporting apparatus according to the present invention can reduce a semiconductor wafer transporting time and provide accuracy and stability of a process by adjusting a position of a semiconductor wafer and distances/heights of hands.

Effects of the present invention are not limited to the above-described effects and should be understood to include all effects which may be inferred from the detailed description of the present invention or elements of the present invention described in the claims.

### DESCRIPTION OF DRAWINGS

FIGS. 1 and 2 are views illustrating a semiconductor wafer transporting apparatus according to one embodiment of the present invention.

FIG. 3 is a detailed view illustrating a hand part (10) and a frame part (20) of FIG. 2.

FIG. 4 is a view illustrating one example of a movable frame (23a, 23b, 23c, 23d) having an opening (H) which is opened.

FIG. 5 is a view illustrating one example of a second connector (45b).

FIG. 6 is a detail view illustrating a guide block (40) of the present invention.

FIG. 7 is a cross-sectional view illustrating ball screws (50, 60) and sliders (70, 80) of the present invention.

### MODES OF THE INVENTION

Hereinafter, disclosed embodiments will be described in detail with reference to accompanying drawings as follows.

First, terms used herein are defined in consideration of functions of the present invention, and should be interpreted based on concepts consistent with the technological scope and meanings commonly or conventionally recognized in the art. In addition, when it is determined that detailed descriptions of related well-known functions or structures unnecessarily obscure the gist of the invention, detailed descriptions thereof will be omitted.

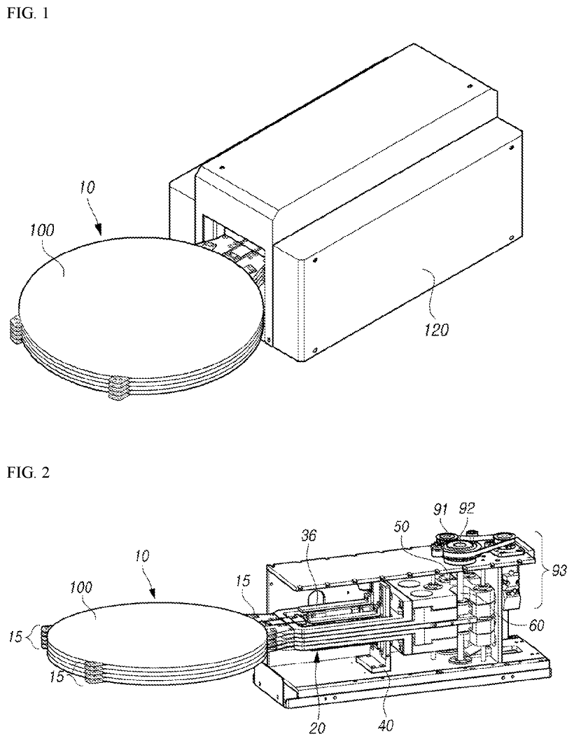

FIG. 1 is a view illustrating a semiconductor wafer transporting apparatus including a cover 120 according to one embodiment of the present invention, and FIG. 2 is a view illustrating the semiconductor wafer transporting apparatus from which the cover 120 is removed according to one embodiment of the present invention.

As illustrated in FIGS. 1 and 2, the semiconductor wafer transporting apparatus according to one embodiment of the present invention include a hand part 10, a frame part 20, cylinders 31, 33a, 33b, 33c, and 33d, a guide block 40, first and second ball screws 50 and 60, and first and second sliders 70 and 80 as main components.

The hand part 10 is for accommodating and supporting one or more semiconductor wafers 100 and may include a fixed hand which are not movable and a plurality of movable hands which are movable, or include only a plurality of movable hands. In this case, the hands are stacked with a predetermined distance therebetween. Although the embodiment of the present invention includes one fixed hand 11 and four movable hands 13a, 13b, 13c, and 13d, the number of the fixed hand and the number of the movable hands may be changed according to a design change.

When the hand part 10 includes one fixed hand 11 and four movable hands 13a, 13b, 13c, and 13d, the hands 11, 13a, 13b, 13c, and 13d may be stacked with a predetermined distance therebetween, and among them, the fixed hand 11 may be positioned at a middle of the movable hands 13a, 13b, 13c, and 13d. That is, the fixed hand 11 is positioned between a second movable hand 13b and a third movable hand 13c.

An end of each of the fixed hand 11 and the movable hands 13a, 13b, 13c, and 13d includes one or more separation prevention members 15 which are to prevent separation of the semiconductor wafer 100 from each of the fixed hand 11 and the movable hands 13a, 13b, 13c, and 13d.

The frame part 20 is for supporting the hands and may include a fixed frame which is not movable and a plurality of movable frames which are movable, or include only a plurality of movable frames. In this case, the frames are stacked with a predetermined distance therebetween.

Since the embodiment of the present invention includes one fixed hand 11 and four movable hands 13a, 13b, 13c, and 13d, the frame part 20 includes one fixed frame 21 and four movable frames 23a, 23b, 23c, and 23d for one-to-one connection therewith. In this case, the fixed frame 21 is positioned between inner movable frames 23b and 23c, and one end of the fixed frame 21 is coupled to the fixed hand 11 to support the fixed hand 11. Similarly, one ends of the movable frames 23a, 23b, 23c, and 23d are coupled to the movable hands 13a, 13b, 13c, and 13d to support and vertically move the movable hands 13a, 13b, 13c, and 13d, respectively.

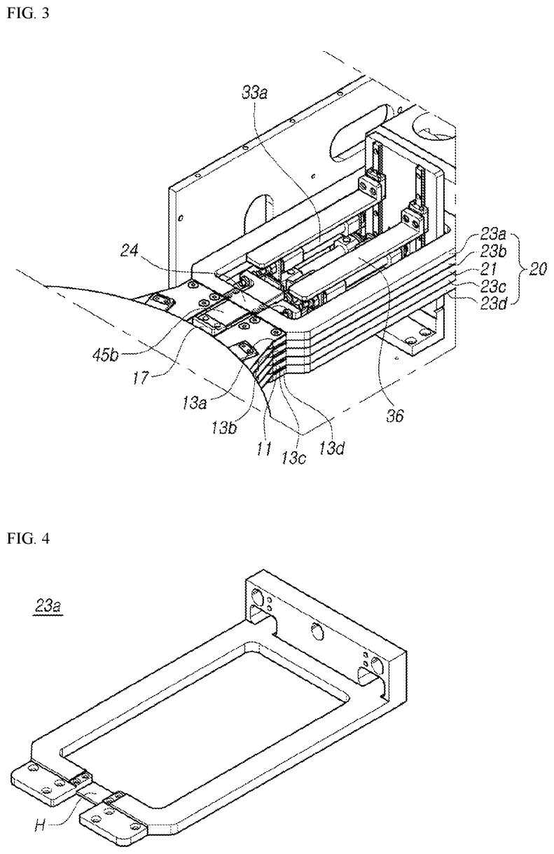

In addition, as illustrated in FIG. 3, the fixed frame 21 and the movable frames 23a, 23b, 23c, and 23d each include a hollow for accommodating the cylinders 31, 33a, 33b, 33c, and 33d and the guide block 40. The fixed frame 21 and the movable frames 23a, 23b, 23c, and 23d may each have a hollow having a size and shape in consideration of the cylinders 31, 33a, 33b, 33c, and 33d which move along the guide block 40.

The cylinders of the present invention are for providing power to stoppers 17 which adjust positions of the semiconductor wafers 100 and may include a fixed cylinder which is not movable and a plurality of movable cylinders which are movable, or include only a plurality of movable cylinders.

Since the embodiment of the present invention includes one fixed hand 11 and four movable hands 13a, 13b, 13c, and 13d, the cylinders include one fixed cylinder 31 and four movable cylinders 33a, 33b, 33c, and 33d for one-to-one matching therewith. The fixed cylinder 31 provides power to the stopper 17 positioned at one side of the fixed hand 11 in order to adjust a position of the semiconductor wafer 100 on the fixed hand 11. The movable cylinders 33a, 33b, 33c, and 33d provide power to stoppers 17 positioned at one sides of the movable hands 13a, 13b, 13c, and 13d in order to adjust positions of the semiconductor wafers 100 on the movable hands 13a, 13b, 13c, and 13d, respectively.

The fixed cylinder 31 and the movable cylinders 33a, 33b, 33c, and 33d may be separately or synchronously operated by the control of a cylinder driving part 39. Particularly, when the semiconductor wafer 100, which is out of a position, is detected by a detection device (not shown), the cylinder driving part 39 may provide power to the stopper 17 separately using one of the fixed cylinder 31 and the movable cylinders 33a, 33b, 33c, and 33d. The cylinder driving part 39 may be coupled to an inner housing (not shown) or another component which does not move.

The fixed cylinder 31 and the movable cylinders 33a, 33b, 33c, and 33d are coupled to lower surfaces of brackets 36, the bracket 36 coupled to the fixed cylinder 31 is coupled to a sidewall 41 of the guide block 40, and the brackets 36 coupled to the movable cylinders 33a, 33b, 33c, and 33d are coupled to first and second guide rails 42 and 43 of the guide block 40. Accordingly, the fixed cylinder 31 may not move, and the movable cylinders 33a, 33b, 33c, and 33d may vertically move in conjunction with movement of the movable frames 23a, 23b, 23c, and 23d.

A plurality of connectors 45a and 45b are connected between the fixed cylinder 31 and the corresponding stopper 17 and connected between the movable cylinders 33a, 33b, 33c, and 33d and the corresponding stoppers 17. A first connector 45a is coupled to a cylinder rod positioned at a front end of the fixed cylinder 31 and moves the corresponding stopper 17 according to movement of the cylinder rod 311. Second connectors 45b are coupled to cylinder rods positioned at front ends of the movable cylinder 33a, 33b, 33c, and 33d and move the corresponding stoppers 17 according to movement of the cylinder rods.

FIG. 4 is a view illustrating one example of the movable frame 23a having an opening H which is opened. The fixed frame 21 and the movable frames 23a, 23b, 23c, and 23d include the same openings H. As illustrated in FIG. 4, in a state in which the opening H is open, the first and second connectors 45a and 45b are inserted into the openings H of the frames 21, 23a, 23b, 23c, and 23d, and after the first and second connectors 45a and 45b are inserted into the openings H, the cover 24 is coupled to front ends of the frames 21, 23a, 23b, 23c, and 23d in order to close the openings H.

The first connector 45a moves forward and backward through the opening H formed at the front end of the fixed frame 21 and includes a pair of latching hooks G formed on a lower surface thereof to limit a movement range of the corresponding stopper 17. Similarly, the second connectors 45b move through the openings H formed at the front ends of the movable frames 23a, 23b, 23c, and 23d and include pairs of latching hooks G formed on lower surfaces thereof to limit movement ranges of the corresponding stoppers 17 as illustrated in FIG. 5.

The reason why the first and second connectors 45a and 45b are inserted into the openings H is to vertically press the movable cylinder 33a, 33b, 33c, and 33d when the movable frames 23a, 23b, 23c, and 23d are move vertically. In order to move the movable cylinders 33a, 33b, 33c, and 33d, the movable cylinders 33a, 33b, 33c, and 33d may be directly coupled to the movable frames 23a, 23b, 23c, and 23d, but even when the movable frames 23a, 23b, 23c, and 23d and the movable cylinders 33a, 33b, 33c, and 33d are connected through the first and second connectors 45a and 45b, the movable cylinders 33a, 33b, 33c, and 33d may be sufficiently moved vertically. The first and second connectors 45a and 45b may be formed of polyetherether ketone (PEEK) with high heat resistance, chemical resistance, impact resistance, and the like.

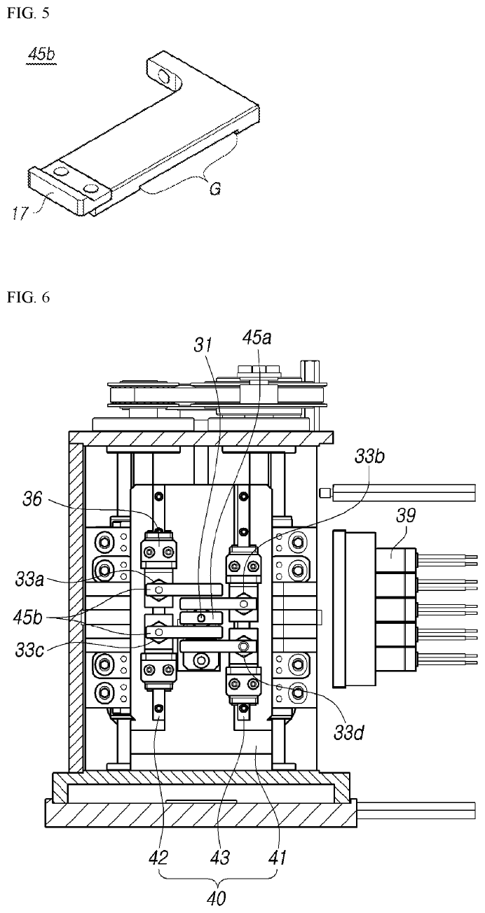

As illustrated in FIG. 6, the guide block 40 is for supporting the fixed cylinder 31 and providing vertical movement passages of the movable cylinders 33a, 33b, 33c, and 33d and includes the sidewall 41 coupled to the fixed cylinder 31, the first guide rail 42 formed in a vertical direction and coupled to some movable cylinders 33a and 33c among the movable cylinders 33a, 33b, 33c, and 33d, and the second guide rail 43 formed in the vertical direction and coupled to the remaining movable cylinders 33b and 33d among the movable cylinders 33a, 33b, 33c, and 33d. The first and second guide rails 42 and 43 are formed on the sidewall 41 with predetermined distances therebetween. According to such a structure, the fixed cylinder 31 may be fixedly coupled to the guide block 40, and the movable cylinders 33a, 33b, 33c, 33d may be vertically moved according to movement of the movable frames 23a, 23b, 23c, and 23d. In this case, the reason why the movable cylinders 33a, 33b, 33c, and 33d are disposed in a left-right direction in a distributed manner is to increase density of the frame part 20 and components positioned therein.

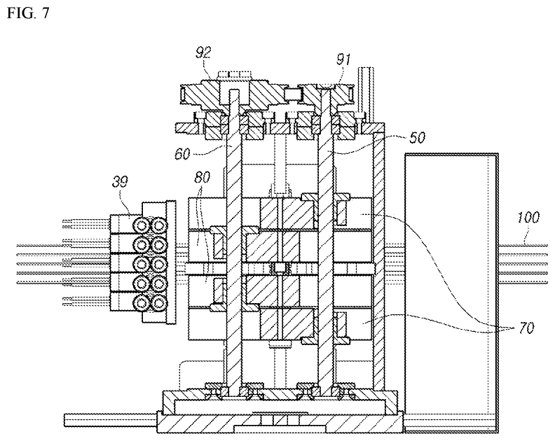

FIG. 7 is a cross-sectional view illustrating ball screws 50 and 60 and sliders 70 and 80.

As illustrated in FIG. 7, the first and second ball screws 50 and 60 are vertically formed with a predetermined distance therebetween, and the plurality of first and second sliders 70 and 80 are formed to move along the first and second ball screws 50 and 60. Since the embodiment of the present invention includes four movable frames 23a, 23b, 23c, and 23d, the embodiment of the present invention includes two first sliders 70 and two second sliders 80 for one-to-one matching therewith.

Two first sliders 70 are coupled to a pair of movable frames among the movable frames 23a, 23b, 23c, and 23d and, particularly, may be coupled to a first movable frame 23a positioned at an uppermost side and a last movable frame 23d positioned at a lowermost side. Two first sliders 70 vertically move two movable frames 23a and 23d according to rotation of the first ball screw 50, in this case, the first sliders 70 move in opposite directions according to rotation of the first ball screw 50, and movement distances of the first sliders 70 are the same. In order to move the first sliders 70 in the opposite directions, the first ball screw 50 includes two sections of which rotation directions of screw threads are opposite.

Two second sliders 80 are coupled to another pair of movable frames among the movable frames 23a, 23b, 23c, and 23d and, particularly, may be coupled to two movable frames 23b and 23c which are positioned between the first movable frame 23a and the last movable frame 23d. Two second sliders 80 vertically move the movable frames 23b and 23c according to rotation of the second ball screw 60, in this case, the second sliders 80 move in opposite directions according to movement of the second ball screw 60, and movement distances of the second sliders 80 are the same. In order to move two second sliders 80 in the opposite directions, the second ball screw 60 includes two sections of which directions of screw threads are opposite to each other.

The first ball screw 50 is formed to pass through the first sliders 70, and the second ball screw 60 is formed to pass through the second sliders 80. In addition, one or more vertical shafts are further included for stable and smooth movement of the first and second sliders 70 and 80 and are formed to pass through the first and second sliders 70 and 80.

The first ball screw 50 is coupled to a first pulley 91 positioned at an upper end thereof, and the second ball screw 60 is coupled to a second pully 92 positioned at an upper end thereof. The first and second pullies 91 and 92 are formed to be rotated together by a driving part 93. In this case, the driving part 93 may include a motor, a rotary shaft, a belt, a tensioner, and the like.

The first pully 91 and the second pully 92 have different diameters, and thus rotational ratios thereof are different from each other. Accordingly, rotational speeds of the first ball screw 50 and the second ball screw 60 are different, and movement speeds and the movement distances of the first slider 70 and the second slider 80 are different.

For example, as in FIG. 7, since the diameter of the first pully 91 is smaller than the diameter of the second pully 92, the first ball screw 50 rotates faster than the second ball screw 60, accordingly, the movement speed of the first slider 70 is greater than the movement speed of the second slider 80, and the movement distance of the first slider 70 is greater than the movement distance of the second slider 80. Accordingly, the outer movable frames 23a and 23d move faster and farther than the inner movable frames 23b and 23c so that distances between the frames 21, 23a, 23b, 23c, and 23d are the same while the first and second sliders 70 and 80 move. As a result, even while the movable frames 23a, 23b, 23c, and 23d move, the distances between the hands 11, 13a, 13b, 13c, and 13d may be the same. In other words, the rotational ratios of the first pully 91 and the second pully 92 are determined to be different in consideration of movement speeds and movement distances of the movable frames 23a, 23b, 23c, and 23d so that the distances between the hands 11, 13a, 13b, 13c, and 13d are the same while the movable frames 23a, 23b, 23c, and 23d move.

As described above, the present invention has been illustrated and described with reference to exemplary embodiments for illustrating the principle of the present invention, but the present invention is not limited to the illustrated and described structure and function. Rather, those skilled in the art may understand that various changes and modifications for the present invention may be made without departing from the spirit and scope of the appended claims.

1. A semiconductor wafer transporting apparatus comprising:
a fixed hand and a plurality of movable hands which support semiconductor wafers;
a fixed frame of which one end is coupled to the fixed hand to support the fixed hand;
a plurality of movable frames of which one ends are coupled to the movable hands to vertically move the movable hands;
a pair of first sliders which are coupled to the other ends of a pair of movable frames among the movable frames and vertically move the pair of movable frames according to rotation of a first ball screw; and
a pair of second sliders which are coupled to the other ends of another pair of movable frames among the movable frames and vertically move the another pair of movable frames according to rotation of a second ball screw.

2. The semiconductor wafer transporting apparatus of claim 1, wherein:
the fixed hand is positioned at a middle of the movable hands; and
the fixed frame is positioned at a middle of the movable frames.

3. The semiconductor wafer transporting apparatus of claim 1, wherein:
rotational speeds of the first ball screw and the second ball screw are different; and
movement speeds of the first sliders and the second sliders are different.

4. The semiconductor wafer transporting apparatus of claim 1, wherein:
the first sliders move in opposite directions each other according to the rotation of the first ball screw; and
the second sliders move in opposite directions each other according to the rotation of the second ball screw.

5. The semiconductor wafer transporting apparatus of claim 1, wherein:
the pair of movable frames coupled to the first sliders are a first movable frame positioned at an uppermost side and a last movable frame positioned at a lowermost side; and
the another pair of movable frames coupled to the second sliders are two movable frames positioned between the first movable frame and the last movable frame.

6. The semiconductor wafer transporting apparatus of claim 1, further comprising:
a fixed cylinder which provides power to a stopper positioned at one side of the fixed hand to adjust a position of the semiconductor wafer on the fixed hand;
a plurality of movable cylinders which vertically move according to the movement of the movable frames and provide power to stoppers positioned at one sides of the movable hands to adjust positions of the semiconductor wafers on the movable hands; and
a guide block which provides vertical movement passages of the movable cylinders.

7. The semiconductor wafer transporting apparatus of claim 6, wherein the movable cylinders vertically move according to the movement of the movable frames.

8. The semiconductor wafer transporting apparatus of claim 6, wherein the guide block includes:
a sidewall coupled to the fixed cylinder;
a first guide rail vertically formed and coupled to some movable cylinders among the movable cylinders; and
a second guide rail vertically formed and coupled to the remaining movable cylinders among the movable cylinders.

9. The semiconductor wafer transporting apparatus of claim 6, wherein the fixed frame and the movable frames each have a hollow to accommodate the guide block therein.

10. The semiconductor wafer transporting apparatus of claim 6, further comprising a plurality of connectors connected between the fixed cylinder and the stopper and connected between the movable cylinders and the stoppers.

11. The semiconductor wafer transporting apparatus of claim 10, wherein the connectors move through openings formed at one ends of the fixed frame and the movable frames.

12. The semiconductor wafer transporting apparatus of claim 10, wherein each of the connectors includes a pair of latching hooks formed on one surface thereof to limit a movement range of the stopper.

13. The semiconductor wafer transporting apparatus of claim 1, further comprising:
a first pully coupled to the first ball screw;
a second pully coupled to the second ball screw; and
a driving part which drives the first pully and the second pully,
wherein rotational ratios of the first pully and the second pully are differently set in consideration of movement speeds and movement distances of the movable frames.

14. A semiconductor wafer transporting apparatus comprising:
a plurality of movable hands which support semiconductor wafers;
a plurality of stoppers positioned at one sides of the movable hands to adjust positions of the semiconductor wafers on the movable hands;
a plurality of movable frames of which one ends are coupled to the movable hands to vertically move the movable hands;
a pair of first sliders which are coupled to the other ends of a pair of movable frames among the movable frames and vertically move the pair of movable frames according to rotation of a first ball screw;
a pair of second sliders which are coupled to the other ends of another pair of movable frames among the movable frames and vertically move the another pair of movable frames according to rotation of a second ball screw; and
a plurality of movable cylinders which vertically move according to the movement of the movable frames and provide power to the stoppers.

15. The semiconductor wafer transporting apparatus of claim 14, further comprising:
a fixed cylinder which provides power to a stopper positioned at one side of the fixed hand to adjust a position of the semiconductor wafer on the fixed hand; and
a guide block which provides vertical movement passages of the movable cylinders.

16. The semiconductor wafer transporting apparatus of claim 15, wherein the guide block includes:
a sidewall coupled to the fixed cylinder;
a first guide rail vertically formed and coupled to some movable cylinders among the movable cylinders; and
a second guide rail vertically formed and coupled to the remaining movable cylinders among the movable cylinders.
